(19) United States
(12) Patent Application Publication
(10) Pub. No.: US 2003/0072463 A1
(43) Pub. Date: Apr. 17, 2003

(54) Sound-activated song selection broadcasting apparatus

(75) Inventor: Tonny Chen, Chang-Hua (TW)

Correspondence Address: DOUGHERTY & TROXELL, SUITE 1404, 5205 LEESBURG PIKE, FALLS CHURCH, VA, 22041, US

(73) Assignee: E-Lead Electronic Co., Ltd.

(21) Appl. No.: 09/978,107

(22) Filed: Oct. 17, 2001

(51) Int. Cl. H04R 3/00; H03G 3/20; G10L 11/00

(52) U.S. Cl. 381/110; 704/275

(57) ABSTRACT

A sound-activated song selection broadcasting apparatus allows users to retrieve and broadcast desired music or songs quickly without repeatedly trial-hearing or wasting time. The apparatus consists of a processing unit, an audio recognition search unit, a sample learning unit, a music processing unit, a human machine interface, a music storing unit, an audio input unit and an audio output unit. Users can find out and retrieve the desired song quickly without trial-hearing every song individually.

### BACKGROUND OF THE INVENTION

1. Field of the Invention

The invention relates to a sound-activated song selection broadcasting apparatus and particularly a broadcasting apparatus for rapidly retrieving selected songs by audio signals.

2. Description of the Prior Art

The commonly used musical broadcasting apparatus now available on the market such as MP3, CD players or other multimedia broadcasting devices generally use push buttons to start broadcasting of songs. When users want to select a particular song, they have to scan the contents of every CD and make trial hearing of every song for a short period of time before correctly picking up the desired one. It is not convenient to use. Moreover, the rapid technology innovations have made car-used multi-CD players very popular these days. MP3 is also widely used. The contents and selection of songs are abundant. Conventional song selection methods simply cannot meet users' requirements.

### SUMMARY OF THE INVENTION

In view of aforesaid disadvantages, it is a primary object of the invention to provide a sound-activated song selection broadcasting apparatus that allows users to retrieve desired music or songs quickly without repeatedly trial-hearing.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a system block diagram of the invention.

FIGS. 2A, 2B are operation flowchart of the invention.

### DESCRIPTION OF THE PREFERRED EMBODIMENT

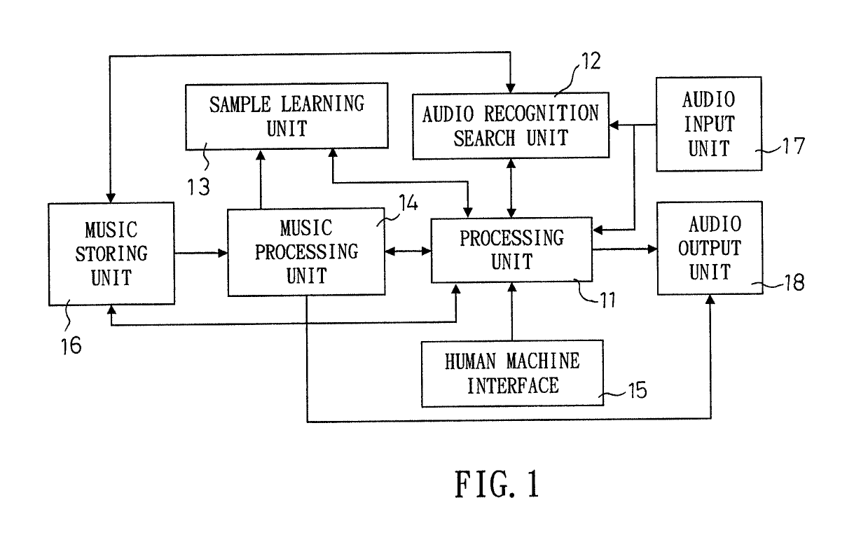

Referring to FIG. 1 for the system block diagram of the invention, the broadcasting apparatus 1 of the invention mainly consists of a processing unit 11, an audio recognition search unit 12, a sample learning unit 13, a music processing unit 14, a human machine interface 15, a music storing unit 16, an audio input unit 17 and an audio output unit 18.

The processing unit 11 is used to coordinate and control the operations of various units of the apparatus 1, and to execute processes and logic calculations related to pre-set programs.

The audio recognition search unit 12 receives audio signals from the audio input unit 17 and converts the audio signals to digital signals readable by the apparatus 1, and authenticates if the signals are acceptable audio commands.

The sample learning unit 13 captures and records characteristic values of every piece of music for users to compare and recognize when entering input sound.

The music processing unit 14 performs processing (such as de-compression or decoding) based on different music formats (such as MP3, WAV, etc.) and broadcasts music.

The human machine interface 15 is an element for setting input for the apparatus, such as pushbuttons, dial plates, or speech-controlled means, etc.

The music storing unit 16 is a medium (such as memory cards, optical disks, or memory devices, or the like) for temporarily storing music (or permanent recording) to provide music data readable to the apparatus 1.

The audio input unit 17 allows users to enter input audio signals, such as a microphone or other audio receiving devices.

The audio output unit 18 is an audio generating element to output music (such as speakers, earphones, etc.).

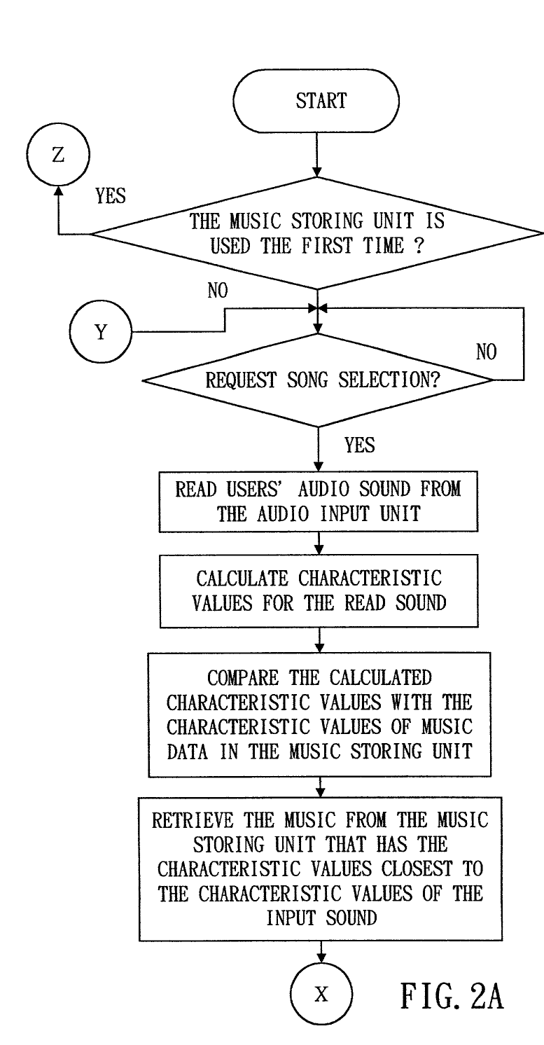

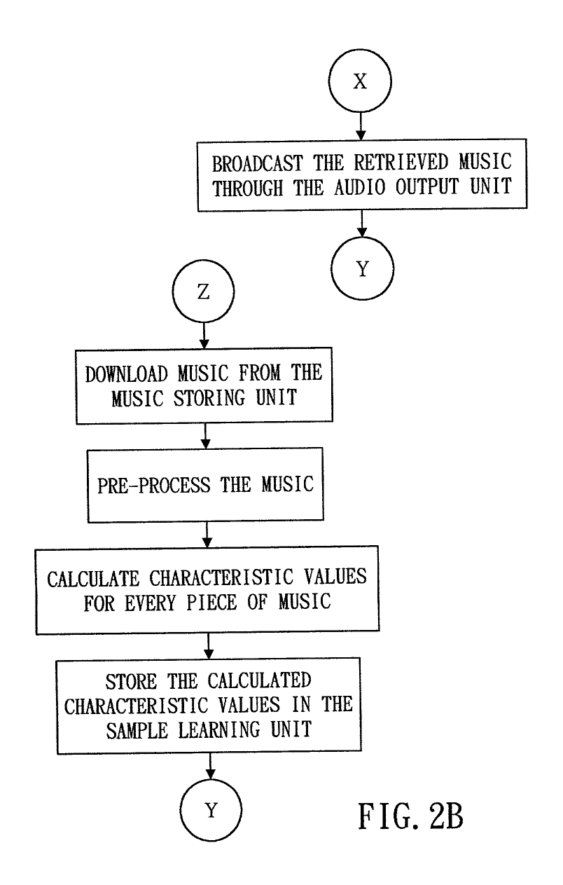

By means of the construction set forth above, users may enter input by speaking voice for the songs desired, either by the names of the song or a fragment of melody. Then the apparatus 1 will search music data stored in the music storing unit 16. The processes are depicted as follows (also referring to FIGS. 1, 2A and 2B):

1. Using the human machine interface 15 to activate the apparatus;

2. Reading music data in the music storing unit 16 to check if there is new addition of music data, if negative, branch to Step 6;

3. When the processing unit 11 detects through the music processing unit 14 new addition of music data, orders the music processing unit 14 to read the music data;

4. Labeling characteristic values of every piece of music to match users' input data, such as melody or name of the song;

5. Temporarily storing the edited data with the characteristic values in the sample learning unit 13;

6. Determining if there is users' commands for selecting song, if negative, waiting for users' commands;

7. Receiving users' input sound from the audio input unit 17 (could be humming melody or name of the song);

8. The audio recognition search unit 12 recognizes audio signals from the audio input unit 17 and provides the processing unit 11 to use;

9. The processing unit 11 compares the recognized audio signals with the learning samples to retrieve the music which has same or similar characteristic as the input audio signals;

10. Transferring the retrieved music to the music processing unit 14 for processing and output through the audio output unit 18;

11. Returning to Step 6.

In summary, the invention presets characteristic values for every piece of music data and allows users to input characteristic sound in the most convenient way to broadcast the desired music rapidly without the troubles of scanning every piece of music data.

While the preferred embodiment of the invention has been set forth for the purpose of disclosure, modifications of the disclosed embodiment of the invention as well as other embodiment thereof may occur to those skilled in the art. Accordingly, the appended claims are intended to cover all embodiments which do not depart from the spirit and scope of the invention.

I claim:

1. A sound-activated song selection broadcasting apparatus for users to broadcast selected sounds through a sound-activated means, comprising a processing unit, an audio recognition search unit, a sample learning unit, a music processing unit, a human machine interface, a music storing unit, an audio input unit and an audio output unit, wherein:
the processing unit coordinates and controls operations of the apparatus and executes processes and logic calculations related to preset programs;
the audio recognition search unit receives audio signals from the audio input unit and converts the audio signals to digital signals readable to the apparatus, and authenticates acceptability of the audio signals for audio commands;
the sample learning unit captures and records characteristic values of each music for users to compare and recognize when entering input sound;
the music processing unit processes and broadcasts music according to selected music formats;
the human machine interface is for setting input for the apparatus;
the music storing unit is for temporarily storing the music to provide music data readable to the apparatus;
the audio input unit allows users to enter audio signals; and
the audio output unit is to output music in audio fashion.

2. The sound-activated song selection broadcasting apparatus of claim 1, wherein the human machine interface is selected from the group consisting of pushbuttons, dial plates, and audio-controlled means.

3. The sound-activated song selection broadcasting apparatus of claim 1, wherein the music storing unit is a medium for temporarily storing or permanently recording music, and is selected from the group consisting of memory cards, optical disks, and memory devices.
